(19) United States
(12) Patent Application Publication
(10) Pub. No.: US 2006/0188110 A1
(43) Pub. Date: Aug. 24, 2006

(54) Electronic apparatus having automatic lifting/lowering device

(76) Inventor: Kuan-Wei Chen, Taipei (TW)

Correspondence Address: NIKOLAI & MERSEREAU, P.A., 900 SECOND AVENUE SOUTH, SUITE 820, MINNEAPOLIS, MN, 55402, US

(21) Appl. No.: 11/062,388

(22) Filed: Feb. 22, 2005

(51) Int. Cl. H04R 1/02; H05K 5/00

(52) U.S. Cl. 381/87; 381/386; 181/150

(57) ABSTRACT

An electronic apparatus having an automatic lifting/lowering device includes a casing and a piston. The piston is installed inside the casing having a rack gear. The piston includes a loudspeaker mounted on top of the internal machine. A power source drives an electrical motor to move with the electronic apparatus installed at an appropriate location. The electrical motor is coupled with the rack gear correspondingly. When the power of the electronic apparatus is on, the electrical motor and the rack gear move oppositely, so as to make the electronic apparatus on top of the piston protrude from the casing. When the power of the electronic apparatus is off, the electrical motor makes relative motion in a reverse direction with the rack gear, so that the electronic apparatus of the piston is drawn back inside the casing.

### BACKGROUND OF THE INVENTION

1. Field of the Invention

The invention relates in general to an electronic apparatus having an automatic lifting/lowering device, and more particularly to a lifting/lowering device in which an on/off status of a power supply of the electronic apparatus determines a lifting/lowering movement.

2. Description of the Related Art

Nowadays people have heavy work stress due to working hard to increase income in the busy society. Many people seek ways to release pressure, and bathing at spas is one of the favored activities. In order to provide customers a relaxing spa bath, loudspeakers surround bathing pools play soothing music. Regarding the music reproduction equipment, a hidden design is taken for the loudspeaker of the SPA bathing pools. That is the loudspeakers are hidden inside a structure body when not in use. In addition, a recoverable elastic lifting/lowering mechanism is provided. Thus, the loudspeakers can emerge from the structure body by using elasticity yet when they are pressed downwards they remain there with the stored elasticity created by the manual pushing down of the loudspeakers.

The structure of the elastic lifting/lowering mechanism as described above is simple and easy to operate. However, in order to make the soothing music play in every corner of the bathing area, more loudspeakers should be configured in some specified sites. As the quantity of the loudspeakers increases, users have to lower and lift the loudspeakers one by one, which is very inconvenient.

### SUMMARY OF THE INVENTION

An electronic apparatus having an automatic lifting/lowering device includes a casing and a piston. The piston is installed inside the casing, which has a rack gear. The piston includes a loudspeaker mounted above the piston. An electrical motor of the electronic apparatus driven by a power source to move is installed at an appropriate location. The electrical motor is coupled with the rack gear correspondingly. When the power of the electronic apparatus is on, the electrical motor and the rack gear move oppositely, so as to make the electronic apparatus above the piston extend outside the casing. When the power of the electronic apparatus is off, the electrical motor makes relative motion in a reverse direction with the rack gear, so that the electronic apparatus of the piston is drawn back inside the casing.

### BRIEF DESCRIPTION OF THE DRAWINGS

FIG. 1 is a perspective view of the present invention.

FIG. 2 is an exploded perspective view of the present invention.

FIG. 3 is side view of the present invention in a raised condition, wherein a part of a housing is removed for clarity.

FIG. 4 is a side view of the present invention in a lowered condition, wherein a part of a housing is removed for clarity.

FIG. 5 is a perspective view of the present invention in a lowered condition.

FIG. 6 is a perspective view of the present invention in a raised condition.

### DETAILED DESCRIPTION OF THE INVENTION

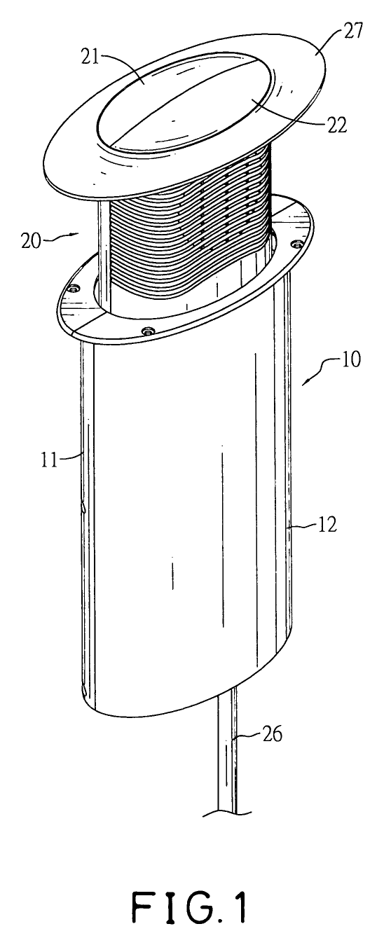

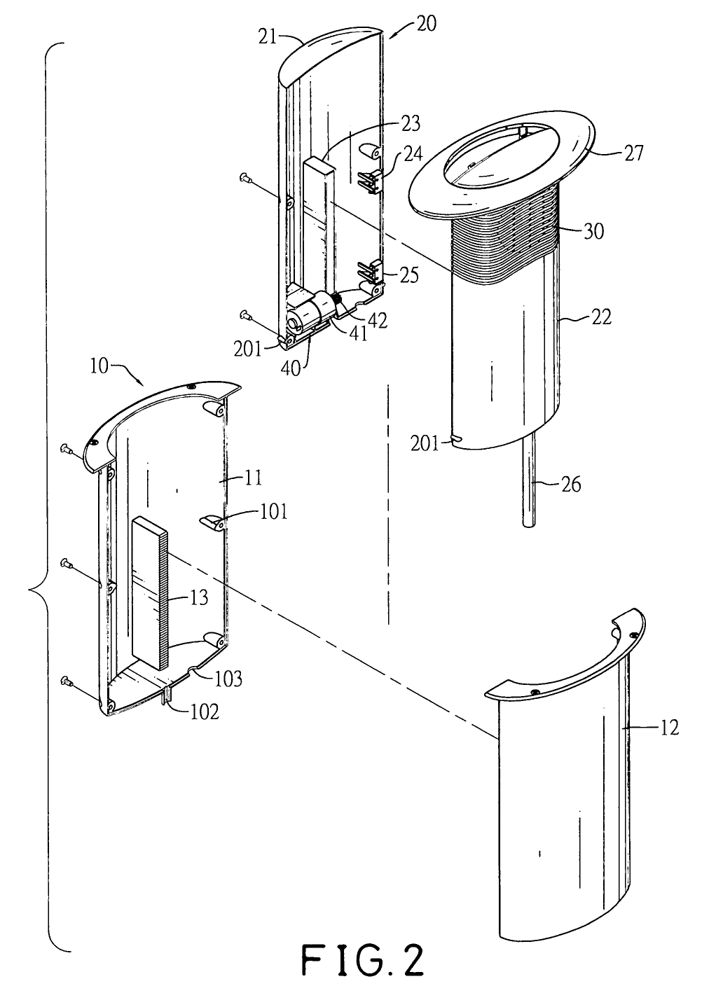

Referring to FIGS. 1 and 2, a preferred embodiment example of the present invention is shown. A piston 20 is reciprocally received inside a casing 10. The casing 10 includes an upper opening. An electric apparatus such as a loudspeaker 30 (as shown in FIG. 2) is configured above the piston 20, which can protrude from the upper opening of the casing 10 and draw back inside the casing 10 by means of a control. FIG. 1 shows a protruded condition of the loudspeaker 30. Nevertheless, the electronic apparatus is not limited to being a loudspeaker and can be other electronic devices that require a similar set up. The following describes detailed structures of the above-mentioned parts.

Still referring to FIGS. 1 and 2, the casing 10 comprises first and second symmetric shells 11, 12, and the piston 20 comprises first and second walls 21, 22, with the loudspeaker 30 fitted on top of second wall 22. Each shell 11,12 has a solid bottom, an interior wall, a rim, and an open top forming an opening when the shells 11,12 are combined. The opening and the interior walls are configured to mate with an exterior of the piston 20. The rims make a peripheral lip at the top of the housing and provide stiffness to the housing. A rack gear 13 is formed upright on the interior wall of the first shell 11. The rack gear 13 of the casing 10 is a longitudinal rack at an internal side. Through holes and screw holes are respectively formed on peripheries of the first and second shells 11,12 whereby the first and second shells 11,12 can be precisely and securely mated together through alignment of the through holes and screw holes. A drain hole may be further provided between the solid bottoms of the shells.

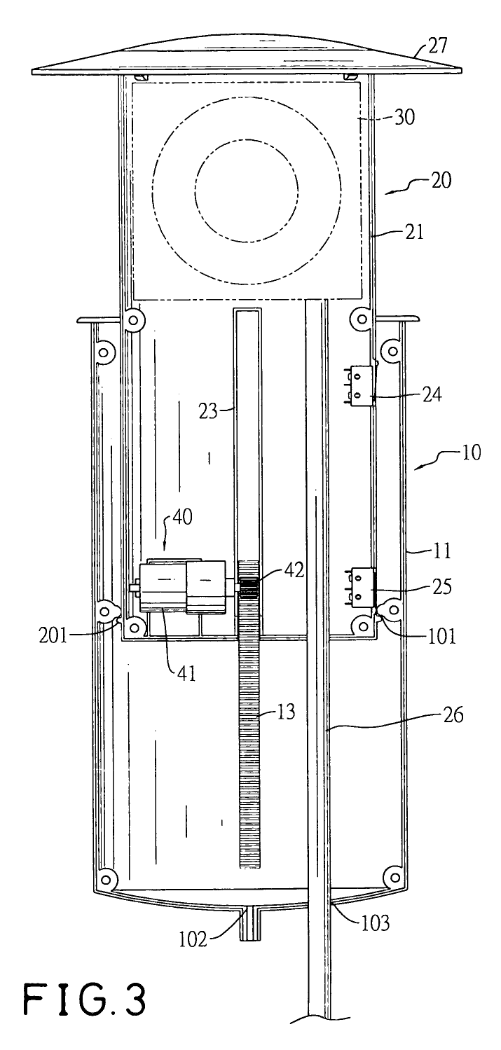

Referring to FIGS. 2 and 3, the first wall 21 of the piston 20 includes a hollow substantially rectangular protrusion 23, which is clearly shown in FIG. 3, configured to receive the rack gear 13 of the casing 10. The protrusion 23 extends inward from an inner face of the first wall 21, has a bottom opening and defines a slot into and through which the rack gear 13 extends via the bottom opening. An electric motor 40 with a pinion gear 42 is mounted adjacent the protrusion 23 such that the pinion gear 42 aligns with the slot of the protrusion 23 and the rack gear 13. The motor 41 is connected with a supply of electricity in a conventional manner. Moreover, at least two top ribs 101 are formed on the shells of the casing 10, and at least two bottom ribs 201 of the piston 20 are formed in the housing and define a space to smoothly receive the piston 20, whereby the piston 20 can be raised and lowered without shake or judder.

The loudspeaker 30 is mounted on a top of the second wall 22 and a flange 27 is formed on a top of the loudspeaker 30. The flange 27 is configured so as to overlap the lip of the casing 10 such that precipitation either falling naturally as rain or artificially as spray is deflected from entering the casing 10 and the loudspeaker 30. The flange 27 is larger than the lip of casing 10. An upper travel limit switch 24 and a lower travel limit switch 25 are fitted to the piston 20 on a middle part and a bottom part of the first wall 21 respectively, and are in connection with the power supply and the electric motor 40. The speaker 30 is also in connection with the power supply. Motion contacts (not shown in the diagram) of the upper/lower travel limit switch 24, 25 are protruding outside the first wall 21, so as to correspond to the corresponding structure of the casing 10 to achieve an objective of limiting upper and lower locations.

Further, a drain hole 102 and an opening 103 are formed at the bottom of the first shell 11 and the second shell 12 of the casing 10. The drain hole 102 is for drainage in case water permeates into the casing 10. The opening 103 is for a distribution line tube 26 of the piston 20 to mobile go through. The distribution line tube 26 of the piston 20 is for receiving lines of the electronic apparatus 30 and the electrical motor 40. An end of the distribution line tube 26 is connected with the piston 20, and the other end of the distribution line tube 26 is mobile to go through the opening 103 of the casing 10.

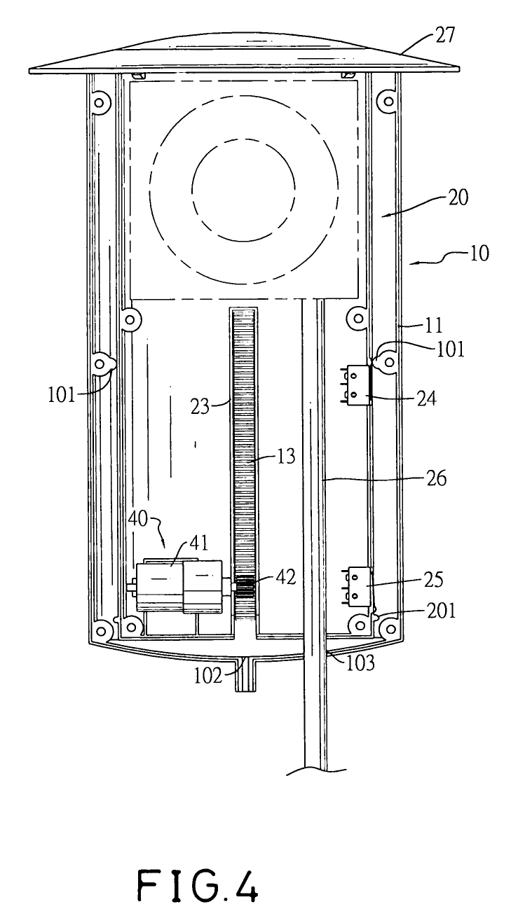

In operation, as shown in FIGS. 3 and 4, the piston 20 is reciprocally received in the casing 10 and operated by the pinion gear 42 of the electronic motor 40 drivingly engaging with the rack gear 13 of the casing 10. In particular reference to FIG. 3, the piston 20 is at a raised position wherein the lower travel limit switch 25 is actuated by the respective rib, and the speaker 30 can produce appropriate sounds. In reference to FIG. 4, the piston 20 is at its lowered position wherein the upper travel limit switch 24 is actuated by the respective rib and the speaker is safely concealed within the casing 10.

It is to be appreciated that the electrical connections of the speaker 30, electric motor 40, upper and lower travel limit switches 24, 25 to the electrical power supply are such that when the speaker 30 is required to produce sounds, application of electrical current to the speaker 30 simultaneously triggers activation of the electrical motor 40 such that the piston 20 rises and the speaker 30 emerges from the casing 10, and vice-versa, when the electrical current to the speaker 30 is terminated, the piston 20 and speaker 30 are lowered into the casing 10 by the deactivation of the electrical motor 40.

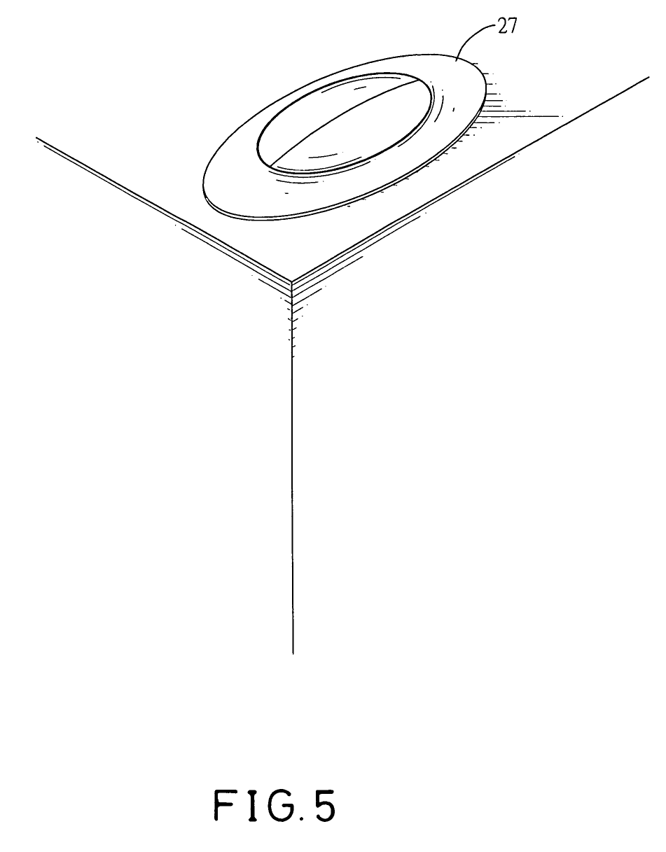

From the above descriptions, the embodiment structure and operating principles of the present invention can be configured at an unspecified structure body at the installation site by using a converter according to the design of the present invention as shown in FIG. 5.

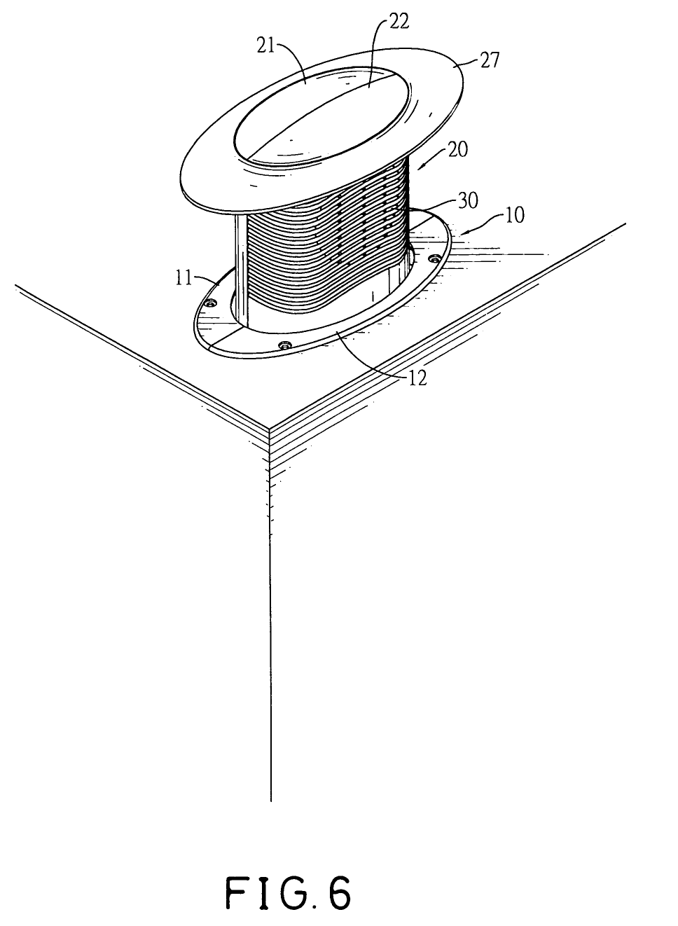

As soon as the electronic apparatus 30 is required for use, the piston 20 can be driven to stretch outside the casing 10 while the power of the electronic apparatus is on as shown in FIG. 6. Since the electronic apparatus 30 requires starting the power when working, and also the power of the electronic apparatus 30 has to be terminated when not in use, the design of the present invention of the electronic apparatus having an automatic lifting/lowering device can be controlled by the power of the electronic apparatus. Thereby no matter how many quantities of the electronic apparatuses are provided, all of the electronic apparatus can be lifted or lowered down while the power supply is on or off. And thus the inconvenient manual control of the conventional electronic apparatus is effectively solved, so as to become more convenient and practical.

The apparatus of the present invention has the following advantages:

Because the raising and lowering of the speaker is simultaneous and automatic with the activation of the speaker, a user no longer needs to manually raise and lower the speaker.

Danger from water entering a speaker that has not been lowered after use, possibly due to forgetfulness of the operator, is eliminated.

Enhance usage of facilities. In the prior art, the nuisance for an operator of having to go around manually raising and lowering the speakers was such that it was common to not bother with such a chore and instead dispense with the music. The present invention renders ease of use such that the users of the spa can always enjoy maximum benefit and relation due to the enhancement provided by music.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An electronic apparatus having an automatic lifting/lowering device comprising:
a casing for burying inside an unspecified structure body at an installation site; wherein the casing comprises an upper opening forming a hollow with a rack gear inside the casing;
a piston installed inside the casing comprising an electronic apparatus above the piston, wherein an electrical motor which is driven to move together with the electronic apparatus by a power source is installed at an appropriate location;
wherein the electrical motor is coupled with the rack gear correspondingly; wherein
the electrical motor moves together with an on/off power status of the electronic apparatus; when the power of the electronic apparatus is on, the electrical motor and the rack gear move oppositely, so as to make the electronic apparatus above the piston stretch outside the casing; wherein when the power of the electronic apparatus is off, the electrical motor makes relative motion in a reverse direction with the rack gear, so that the electronic apparatus of the piston is drawn back inside the casing.

2. The electronic apparatus having an automatic lifting/lowering device as defined in claim 1, wherein the rack gear of the casing is a longitudinal rack at an internal side, wherein the electrical motor of the piston comprises a pinion gear configured on an axle center of a motor, wherein the pinion gear is meshed with the longitudinal rack of the casing.

3. The electronic apparatus having an automatic lifting/lowering device as defined in claim 2, wherein two top ribs are formed respectively at two opposite locations of internal walls of the casing, wherein two bottom ribs are formed respectively at opposite locations of external walls of the piston, wherein the bottom ribs are located below an external side of the top ribs for setting a limit of a lifting distance of the piston.

4. The electronic apparatus having an automatic lifting/lowering device as defined in claim 3, wherein the piston comprises an upper travel limit switch and a lower travel limit switch in a middle part and in a bottom part respectively, wherein motion contacts of the upper/lower travel limit switch are protruding outside a side wall of the piston responding to the top ribs of the casing.

5. The electronic apparatus having an automatic lifting/lowering device as defined in claim 1, wherein a bottom of the casing forms an opening, wherein the piston is configured with a distribution line tube for receiving the electronic apparatus and a line of electrical motor, wherein an end of the distribution line tube is connected with the piston, and the other end of the distribution line tube is mobile to go through the opening of the casing.

6. The electronic apparatus having an automatic lifting/lowering device as defined in claim 1, wherein the casing comprises first and second symmetric shells, and the piston comprises first and second walls, wherein the casing is configured with the rack gear on an internal wall of the first shell, wherein the piston forms a hollow substantially rectangular protrusion on the corresponding first wall, wherein the protrusion is provided for the rack gear on the casing to go through inside the piston to couple with the electrical motor.

7. The electronic apparatus having an automatic lifting/lowering device as defined in claim 2, wherein the casing comprises first and second symmetric shells, and the piston comprises first and second walls, wherein the casing is configured with the rack gear on an internal wall of the first shell, wherein the piston forms a hollow substantially rectangular protrusion on the corresponding first wall, wherein the protrusion is provided for the rack gear on the casing to go through inside the piston to couple with the electrical motor.

8. The electronic apparatus having an automatic lifting/lowering device as defined in claim 3, wherein the casing comprises first and second symmetric shells, and the piston comprises first and second walls, wherein the casing is configured with the rack gear on an internal wall of the first shell, wherein the piston forms a hollow substantially rectangular protrusion on the corresponding first wall, wherein the protrusion is provided for the rack gear on the casing to go through inside the piston to couple with the electrical motor.

9. The electronic apparatus having an automatic lifting/lowering device as defined in claim 4, wherein the casing comprises first and second symmetric shells, and the piston comprises first and second walls, wherein the casing is configured with the rack gear on an internal wall of the first shell, wherein the piston forms a hollow substantially rectangular protrusion on the corresponding first wall, wherein the protrusion is provided for the rack gear on the casing to go through inside the piston to couple with the electrical motor.

10. The electronic apparatus having an automatic lifting/lowering device as defined in claim 5, wherein the casing comprises first and second symmetric shells, and the piston comprises first and second walls, wherein the casing is configured with the rack gear on an internal wall of the first shell, wherein the piston forms a hollow substantially rectangular protrusion on the corresponding first wall, wherein the protrusion is provided for the rack gear on the casing to go through inside the piston to couple with the electrical motor.

11. The electronic apparatus having an automatic lifting/lowering device as defined in claim 6, wherein a top of the piston is installed with a flange, wherein the flange is larger than a lip of casing, so that the flange can completely cover the lip of the casing.

12. The electronic apparatus having an automatic lifting/lowering device as defined in claim 7, wherein a top of the piston is installed with a flange, wherein the flange is larger than a lip of casing, so that the flange can completely cover the lip of the casing.

13. The electronic apparatus having an automatic lifting/lowering device as defined in claim 8, wherein a top of the piston is installed with a flange, wherein the flange is larger than a lip of casing, so that the flange can completely cover the lip of the casing.

14. The electronic apparatus having an automatic lifting/lowering device as defined in claim 9, wherein a top of the piston is installed with a flange, wherein the flange is larger than a lip of casing, so that the flange can completely cover the lip of the casing.

15. The electronic apparatus having an automatic lifting/lowering device as defined in claim 10, wherein a top of the piston is installed with a flange, wherein the flange is larger than a lip of casing, so that the flange can completely cover the lip of the casing.

16. The electronic apparatus having an automatic lifting/lowering device as defined in claim 1, wherein the electronic apparatus on the piston is a loudspeaker.

17. The electronic apparatus having an automatic lifting/lowering device as defined in claim 2, wherein the electronic apparatus on the piston is a loudspeaker.

18. The electronic apparatus having an automatic lifting/lowering device as defined in claim 3, wherein the electronic apparatus on the piston is a loudspeaker.

19. The electronic apparatus having an automatic lifting/lowering device as defined in claim 4, wherein the electronic apparatus on the piston is a loudspeaker.

20. The electronic apparatus having an automatic lifting/lowering device as defined in claim 5, wherein the electronic apparatus on the piston is a loudspeaker.
